(19) United States
(12) Patent Application Publication
(10) Pub. No.: US 2015/0380603 A1
(43) Pub. Date: Dec. 31, 2015

(54) LIGHT-EMITTING ELEMENT SUBSTRATE AND LIGHT-EMITTING ELEMENT USING THE SAME

(71) Applicant: PHECDA TECHNOLOGY CO. LTD., Taipei City (TW)

(72) Inventors: Kuang-Ning KUANG, Zhubei City (TW); Chi-Wei LEE, Zhubei City (TW); Jian-Jhih CHEN, Zhubei City (TW)

(21) Appl. No.: 14/542,356

(22) Filed: Nov. 14, 2014

(30) Foreign Application Priority Data
Jun. 26, 2014 (TW) 103211364

(51) Int. Cl. H01L 33/04; H01L 33/10; H01L 33/40

(52) U.S. Cl. CPC H01L 33/04; H01L 33/40; H01L 33/10

(57) ABSTRACT

A light-emitting element substrate and a light-emitting element using the same are disclosed. The light-emitting element substrate includes a transparent substrate and an intermediate layer. The transparent substrate has a plurality of microstructures on a surface thereof, top portion of each microstructure is a plane structure, and an adjacent interval between the plane structures is between 0.5 μm and 2.5 μm, the plurality of microstructures have gaps therebetween, and the intermediate layer is covered on the plane structures for facilitating production of epitaxial layer. In an embodiment, the gaps of the plurality of microstructures are still reserved when the epitaxial layer is grown on the plurality of microstructures so as to improve light extraction efficiency of the light-emitting element using the light-emitting element substrate.

### CROSS-REFERENCE TO RELATED APPLICATION

This application claims priority from Taiwan Patent Application No. 103211364, filed on Jun. 26, 2014, in the Taiwan Intellectual Property Office, the content of which are hereby incorporated by reference in their entirety for all purposes.

### BACKGROUND OF THE INVENTION

1. Field of the Invention

The present disclosure relates to a light-emitting element substrate, more particular to a light-emitting element substrate which can improve light extraction efficiency and accelerate epitaxy velocity of the light-emitting element.

2. Description of the Related Art

The current light-emitting element is to use photo-electric effect theory which transforms electrical energy into light through combination of the excited electrons and electron holes, and to use the semiconductor manufacturing process while making mass production. The light emitting diode is characterized of advantages of longer service life, photoluminescence light-emitting, lower energy consumption, and quicker response speed and without warmup time and so on. In addition, by applying the semiconductor manufacturing process, the light-emitting element even has advantages of smaller volume, impact-resistant, and easy to make mass production and so on, and can further to be manufactured as array or small-size optical element based on the practical needs.

Theoretically, although the whole light generated by combination of electrons and electron holes can be irradiated to outer, and luminescence efficiency by 100% can be achieved, in practical situation, inner structure and material of the light emitting diode cause various light transmission losses such that the luminescence efficiency transmitting to outer is decreased. As a result, how to promote luminescence efficiency by lower energy consumption has become a crucial issue in scholarly societies as well as industry circle.

In mainstream of industry, the microstructure on the surface of pattern sapphire substrate (PSS) is used to increase light extraction efficiency. However, lattices of the III-V group compounds and the sapphire substrate do not match up with each other in the epitaxial manufacturing process, and this problem disables the advancement of epitaxial quality and yield rate thereof, such that the application of pattern sapphire substrate is limited.

According to the preceding description, the inventor of the present disclosure designs a light-emitting element substrate and light-emitting element using the same which aim at improving the shortcomings of the current technique so as to further increase the industrial applicability.

### SUMMARY OF THE INVENTION

In view of the known technical problems, the purpose of the present disclosure is to provide a light-emitting element substrate, wherein a plurality of microstructures having plane top surface is disposed on surface of the substrate, and an intermediate layer is deposited on the plane top surface to lower the follow-up difficulty of epitaxy.

In view of the known technical problems, the purpose of the present disclosure is to provide a light-emitting element substrate which is used to improve the problem concerning lattices of the III-V group compounds and the sapphire substrate do not match up with each other by an intermediate layer so as to effectively promote the production yield and quality.

In view of the known technical problems, the purpose of the present disclosure is to provide a light-emitting element which uses the intermediate layer to accelerate the growth rate of the epitaxial and promote the stability of production quality.

In view of the known technical problems, the purpose of the present disclosure is to provide a light-emitting element which uses gaps reserved between surface microstructures and epitaxial layer to increase light refraction so as to further promote light extraction efficiency of the light-emitting element.

According to purpose of the present disclosure, it provides a light-emitting element substrate which may comprise a transparent substrate and an intermediate layer. The transparent substrate may have a plurality of microstructures on a surface thereof, top portion of each of the microstructures may be a plane structure, wherein an adjacent interval between the plane structures may be between 0.5 μm and 2.5 μm, the plurality of microstructures may have gaps therebetween. The intermediate layer may cover on the plurality of plane structures for facilitating growth of an epitaxial layer.

Preferably, material of the intermediate layer may comprise aluminum nitride and the epitaxial layer is selected from group consisting of III-V group compounds.

Preferably, the transparent substrate may comprise a transparent sapphire substrate, a glass substrate or a crystal substrate.

Preferably, the plurality of microstructures may be distributed uniformly.

Preferably, the epitaxial layer may be grown on the plurality of microstructures and the gaps of the plurality of microstructures may be reserved.

According to the aforementioned purpose, the present disclosure further provides a light-emitting element which may comprise a transparent substrate, an intermediate layer, a first semiconductor layer, a light-emitting layer, a second semiconductor layer, a first ohmic electrode, and a second ohmic electrode. The transparent substrate may have a plurality of microstructures on a surface thereof, top portion of each of the microstructures may be a plane structure, wherein an adjacent interval between the plane structures may be between 0.5 μm and 2.5 μm, the plurality of microstructures may have gaps therebetween. The intermediate layer may cover on the plurality of plane structures. The first semiconductor layer may be disposed on the intermediate layer, the light-emitting layer may be disposed on the first semiconductor layer, the second semiconductor layer may be disposed on the light-emitting layer, the first ohmic electrode may contact with the first semiconductor layer and the second ohmic electrode may contact with the second semiconductor layer, wherein the gaps of the plurality of microstructures between the plurality of microstructures and the first semiconductor layer are reserved.

Preferably, material of the intermediate layer may comprise aluminum nitride.

Preferably, the transparent substrate may comprise a transparent sapphire substrate, a glass substrate or a crystal substrate.

Preferably, the plurality of microstructures may be distributed uniformly.

Preferably, the first ohmic electrode and the second ohmic electrode may be selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.

Preferably, structures of the gaps between the microstructures and the first semiconductor layer may be used to increase light refraction so as to promote light extraction efficiency of the light-emitting element.

The primary purpose of the present disclosure is to provide a light-emitting element substrate and light-emitting element using the same which may have one or more following advantages:

1. Enhancing yield rate and quality: by means of an intermediate layer, it can improve the problem concerning lattices of the III-V group compounds and the sapphire substrate that do not match up with each other in the epitaxial manufacturing process such that the defect of dislocation thereby occurs; depositing an intermediate layer which is formed of aluminum nitride of III group compounds on the substrate and accordingly conducting the epitaxial manufacturing process of III-V group compounds on the intermediate layer enables to promote production yield and decrease the percentage of the defect of dislocation.

2. Promoting light extraction efficiency: when epitaxial is conducted on the intermediate layer, it can form gaps between the microstructures on surface of the substrate and the epitaxial layer, and the gaps increase light refraction so as to promote light extraction efficiency of the light-emitting element.

3. Decreasing manufacturing cost: by controlling the intermediate layer which is characterized of relative stable process parameter, the necessary manufacturing cost for epitaxial is therefore decreased, directly.

Hereinafter, embodiments of the present disclosure will be described in detail with reference to the accompanying drawings so that those skilled in the art to which the present disclosure pertains can realize the present disclosure.

### BRIEF DESCRIPTION OF THE DRAWINGS

FIG. 1 is a schematic diagram of a light-emitting element substrate of the resent disclosure.

FIG. 2 is a schematic diagram of a light-emitting element of the present disclosure.

### DETAILED DESCRIPTION OF THE PREFERRED EMBODIMENTS

Hereinafter, embodiments of the present disclosure will be described in detail with reference to the accompanying drawings so that those skilled in the art to which the present disclosure pertains can realize the present invention. As those skilled in the art would realize, the described embodiments may be modified in various different ways, all without departing from the spirit or scope of the present disclosure.

The exemplary embodiments of the present disclosure will be understood more fully from the detailed description given below and from the accompanying drawings of various embodiments of the disclosure, which, however, should not be taken to limit the disclosure to the specific embodiments, but are for explanation and understanding only.

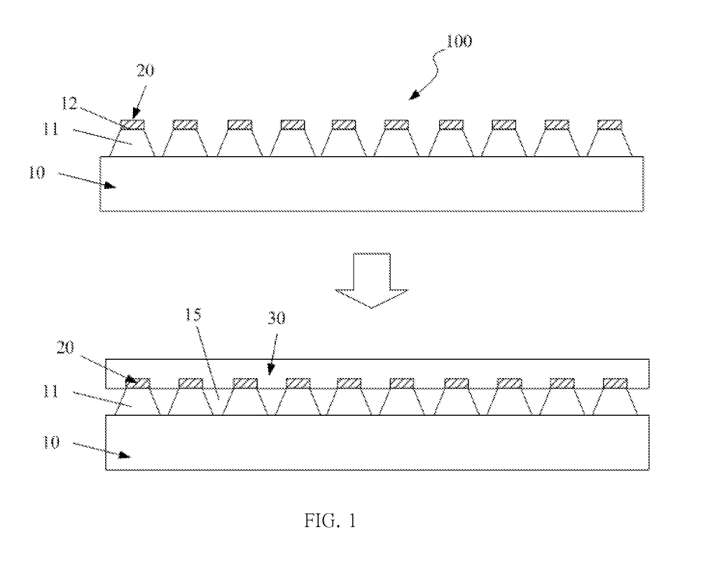

Please refer to FIG. 1 which is a schematic diagram of a light-emitting element substrate of the present disclosure. As shown in FIG. 1, a light-emitting element substrate 100 includes a transparent substrate 10 and an intermediate layer 20. The transparent substrate 10 has a plurality of microstructures 11 on a surface thereof, top portion of each of the microstructures 11 is a plane structure 12, and an adjacent interval between the plane structures 12 is between 0.5 μm and 2.5 μm, the plurality of microstructures have gaps 15 therebetween. The plurality of microstructures 11 are distributed uniformly on the transparent substrate 10. The transparent substrate 10 includes a transparent sapphire substrate, a glass substrate or a crystal substrate.

The intermediate layer 20 is covered on the plane structures 12 for facilitating grown of an epitaxial layer 30. Material of the intermediate layer 20 includes aluminum nitride and the epitaxial layer 30 is selected from group consisting of III-V group compounds.

The light-emitting element substrate 100 of the present disclosure is to deposit the intermediate layer 20 made of aluminum nitride of III group compounds on the plane structure 12 of the plurality of microstructures 11 of the transparent substrate 10, and accordingly conducts the epitaxial manufacturing process of III group compounds on the intermediate layer 20 to improve the dislocation caused by unmatched lattices. As a result, production yield can be boosted and the defect of dislocation can be decreased by applying the intermediate layer 20.

Subsequently, the epitaxial layer 30 is grown on the plurality of microstructures 11, and by an adequate adjacent interval between the plane structures 12, the lateral epitaxial layer 30 can be grown so that the gaps 15 between the plurality of microstructures 11 and the epitaxial layer 30 are reserved. The structures of the gaps 15 increase light refraction so as to promote light extraction efficiency of the light-emitting element.

Furthermore, when the adjacent interval between the plane structures 12 is too smaller, the lateral epitaxial layer 30 tends to have defect as squeezing, and if the adjacent interval between the plane structures 12 is too large, the epitaxial layer 30 is easy to grow into the gaps 15 of the plurality of microstructures 11 to fill the gaps 15 such that the plurality of microstructures 11 fails to increase light extraction efficiency. In applicability, adjacent interval between the plane structures 12 is preferably between 1 μm and 2 μm.

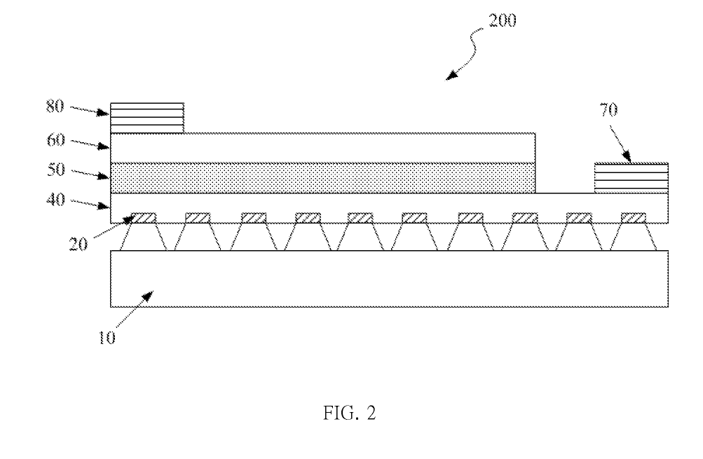

Please refer to FIG. 2 which a schematic diagram of a light-emitting element of the present disclosure. The present disclosure further provides a light-emitting element using the light-emitting element substrate 100. It can be seen from the FIG. that a first semiconductor layer 40, a light-emitting layer 50, a second semiconductor layer 60, a first ohmic electrode 70 and a second ohmic electrode 80 are stacked on the light-emitting element substrate 100 orderly, wherein the first ohmic electrode 70 is connected to the first semiconductor layer 40 and the second ohmic electrode 80 is connected to the first semiconductor layer 40.

Wherein the first semiconductor layer 40, the light-emitting layer 50 and the second semiconductor layer 60 are semiconductor layer of III-V group semiconductor such as gallium nitride semiconductor. As to the first ohmic electrode 70 and the second ohmic electrode 80, they are selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.

In conclusion, a light-emitting element substrate and light-emitting element using the same of the present disclosure is to deposit an intermediate layer on a plane structure to improve the common problem concerning that the lattices do not match up each other and also lower the follow-up difficulty of epitaxy. In addition, by controlling an intermediate layer which is characterized of relative stable process parameter, the necessary manufacturing cost for epitaxial is thereby decreased, directly; in the meanwhile the gaps reserved between the epitaxial layer and the plurality of microstructures are used to increase light refraction of optical surface so as to promote light extraction efficiency of the light-emitting element.

While the means of specific embodiments in present disclosure has been described by reference drawings, numerous modifications and variations could be made thereto by those skilled in the art without departing from the scope and spirit of the disclosure set forth in the claims. The modifications and variations should in a range limited by the specification of the present disclosure.

What is claimed is:

1. A light-emitting element substrate, comprising:
a transparent substrate having a plurality of microstructures on a surface thereof, top portion of each of the microstructures being a plane structure, wherein an adjacent interval between the plane structures is between 0.5 μm and 2.5 μm, the plurality of microstructures have gaps therebetween; and
an intermediate layer covering on the plurality of plane structures for facilitating growth of an epitaxial layer.

2. The light-emitting element substrate of claim 1, wherein material of the intermediate layer comprises aluminum nitride and the epitaxial layer is selected from group consisting of III-V group compounds.

3. The light-emitting element substrate of claim 1, wherein the transparent substrate comprises a transparent sapphire substrate, a glass substrate or a crystal substrate.

4. The light-emitting element substrate of claim 1, wherein the plurality of microstructures are distributed uniformly.

5. The light-emitting element substrate of claim 1, wherein the epitaxial layer is grown on the plurality of microstructures and the gaps of the plurality of microstructures are reserved.

6. A light-emitting element, comprising:
a transparent substrate having a plurality of microstructures on a surface thereof, top portion of each of microstructures being a plane structure, wherein an adjacent interval between the plane structures is between 0.5 μm and 2.5 μm, the plurality of microstructures have gaps therebetween;
an intermediate layer covering on the plurality of plane structures;
a first semiconductor layer disposed on the intermediate layer;
a light-emitting layer disposed on the first semiconductor layer;
a second semiconductor layer disposed on the light-emitting layer;
a first ohmic electrode contacting with the first semiconductor layer; and
a second ohmic electrode contacting with the second semiconductor layer;
wherein the gaps of the plurality of microstructures between the plurality of microstructures and the first semiconductor layer are reserved.

7. The light-emitting element of claim 6, wherein material of the intermediate layer comprises aluminum nitride.

8. The light-emitting element of claim 6, wherein the transparent substrate comprises a transparent sapphire substrate, a glass substrate or a crystal substrate.

9. The light-emitting element of claim 6, wherein the plurality of microstructures are distributed uniformly.

10. The light-emitting element of claim 6, wherein the first ohmic electrode and the second ohmic electrode are selected from at least one alloy or multilayer film consisted of an oxide or a nitride comprising a group of nickel, lead, cobalt, iron, titanium, copper, rhodium, gold, ruthenium, tungsten, zirconium, molybdenum, tantalum, silver.

11. The light-emitting element of claim 6, wherein the gaps are used to increase light refraction so as to promote light extraction efficiency of the light-emitting element.
